(19) United States
(12) Patent Application Publication
(10) Pub. No.: US 2025/0369754 A1
(43) Pub. Date: Dec. 4, 2025

(54) SYSTEM AND METHOD FOR MULTI-MERIT ADAPTIVE SAMPLING IN OVERLAY METROLOGY

(71) Applicant: KLA Corporation, Milpitas, CA (US)

(72) Inventors: Michael Iv, Nesher (IL); Nadav Gutman, Zichron Ya'aqov (IL); Dana Klein, Haifa (IL); Yatir Linden, Zichron Ya’akov (IL); Yoram Uziel, Migdal Ha'emek (IL)

(21) Appl. No.: 18/680,185

(22) Filed: May 31, 2024

(51) Int. Cl. G01B 11/27; G03F 7/00; G06T 7/00

(52) U.S. Cl. CPC G01B 11/272; G03F 7/70633; G03F 7/706833; G03F 7/706837; G06T 7/0004; G06T 2207/30148

(57) ABSTRACT

A method for multi-merit adaptive sampling may include receiving an initial sampling map and a first set of metrology data. The method may further include calculating figure of merit metrics. The method may include ranking each initial sampling point in the initial sampling map based on the figure of merit metrics and levels of process variation. The method may include generating an adjusted sampling plan for at least one of a second sample in the first lot or a future process layer of the first sample based on the rank of each initial sampling point. An adjusted set of sampling points may be generated by increasing a number of sampling points in a first sample region associated with a first level of process variation and decreasing a number of sampling points in a second sample region associated with a second level of process variation.

### TECHNICAL FIELD

The present disclosure is related generally to overlay metrology and, more particularly, to a system and method for multi-merit adaptive sampling in overlay metrology.

### BACKGROUND

In the semiconductor industry, modern chip devices may be made of stacked wafers and dies. Overlay targets (or alignment marks) are printed on the stacked wafers and dies in different locations for the purpose of overlay metrology and process control. Conventional overlay control schemes rely on measuring some subset of overlay targets on a sample for modeling overlay errors and calculating scanner correctables.

Some overlay control schemes utilize static (or fixed) sampling techniques which rely on fixed rules that remain constant throughout the product process. The main disadvantage of static sampling is that it may not be the most effective at detecting process excursions as quickly as they occur. For example, lot-to-lot and/or wafer-to-wafer variances are not taken into account so over sampling and under sampling occurs at some process levels, impacting the effectiveness of the metrology resources. Further, static sampling increases the cost of ownership due to maladaptive time and complexity without providing significant additional insights of improvements in accuracy.

Conversely, other sampling techniques adjust the rules during the product process. For example, dense sampling techniques increase the number of sampling points. Denser sampling techniques may improve accuracy by providing more detailed information about the wafer's features and variations. However, with increased sampling, the computational load and correction complexity during the alignment process is also increased, thus impacting the cost of ownership.

Therefore, there is a need for a system and method for multi-merit adaptive sampling in overlay metrology.

### SUMMARY

A system for multi-merit adaptive sampling is disclosed, in accordance with one or more embodiments of the present disclosure. In embodiments, the system includes: a controller communicatively coupled to a metrology sub-system and a fabrication sub-system, the controller including one or more processors configured to execute program instructions configured to cause the one or more processors to: receive an initial sampling map for at least a first sample of the one or more samples in a first lot of the one or more sample lots, wherein the initial sampling map includes a first set of sampling points; receive a first set of metrology data from at least the first sample of the one or more samples from the metrology sub-system based on the first set of sampling points of the initial sampling map; calculate a plurality of figure of merit metrics indicative of process variation based on the first set of metrology data; rank each initial sampling point of the first set of sampling points in the initial sampling map based on the plurality of calculated figure of merit metrics and one or more levels of process variation; generate an adjusted sampling plan for at least one of a second sample of the one or more samples in the first lot of the one or more sample lots or a future process layer of the first sample of the one or more samples in the first lot based on the rank of each initial sampling point of the first set of sampling points, wherein the adjusted sampling plan includes an adjusted set of sampling points different than the first set of sampling points, wherein the adjusted set of sampling points is generated by increasing a number of sampling points in a first sample region of the first sample associated with a first level of process variation and decreasing a number of sampling points in a second sample region of the first sample associated with a second level of process variation, wherein the first level of process variation is greater than the second level of process variation; provide the generated adjusted sampling plan to the metrology sub-system; generate one or more correctables based on the plurality of calculated figure of merit metrics.

A system for multi-merit adaptive sampling is disclosed, in accordance with one or more embodiments of the present disclosure. In embodiments, the system includes: a metrology sub-system configured to perform metrology measurements on one or more samples in one or more sample lots; and a controller communicatively coupled to the metrology sub-system, the controller including one or more processors configured to execute program instructions configured to cause the one or more processors to: receive an initial sampling map for at least a first sample of the one or more samples in a first lot of the one or more sample lots, wherein the initial sampling map includes a first set of sampling points; receive a first set of metrology data from at least the first sample of the one or more samples from the metrology sub-system based on the first set of sampling points of the initial sampling map; calculate a plurality of figure of merit metrics indicative of process variation based on the first set of metrology data; rank each initial sampling point of the first set of sampling points in the initial sampling map based on the plurality of calculated figure of merit metrics and one or more associated levels of process variation; generate an adjusted sampling plan for at least one of a second sample of the one or more samples in the first lot of the one or more sample lots or a future process layer of the first sample of the one or more samples in the first lot based on the rank of each initial sampling point of the first set of sampling points, wherein the adjusted sampling plan includes an adjusted set of sampling points different than the first set of sampling points, wherein the adjusted set of sampling points is generated by increasing a number of sampling points in a first sample region of the first sample associated with a first level of process variation and decreasing a number of sampling points in a second sample region of the first sample associated with a second level of process variation, wherein the first level of process variation is greater than the second level of process variation; provide the generated adjusted sampling plan to the metrology sub-system; and generate one or more correctables based on the plurality of calculated figure of merit metrics.

A method for multi-merit adaptive sampling is disclosed, in accordance with one or more embodiments of the present disclosure. In embodiments, the method includes: receiving an initial sampling map for at least a first sample of one or more samples in a first lot of one or more sample lots, wherein the initial sampling map includes a first set of sampling points; generate a first set of metrology data from at least the first sample of the one or more samples using a metrology sub-system based on the first set of sampling points of the initial sampling map; calculate a plurality of figure of merit metrics indicative of process variation based on the first set of metrology data; rank each initial sampling point of the first set of sampling points in the initial sampling map based on the plurality of calculated figure of merit metrics and one or more associated levels of process variation; generate an adjusted sampling plan for at least one of a second sample of the one or more samples in the first lot of the one or more sample lots or a future process layer of the first sample of the one or more samples in the first lot based on the rank of each initial sampling point of the first set of sampling points, wherein the adjusted sampling plan includes an adjusted set of sampling points different than the first set of sampling points, wherein the adjusted set of sampling points is generated by increasing a number of sampling points in a first sample region of the first sample associated with a first level of process variation and decreasing a number of sampling points in a second sample region of the first sample associated with a second level of process variation, wherein the first level of process variation is greater than the second level of process variation; provide the generated adjusted sampling plan to the metrology sub-system; generate one or more correctables based on the plurality of calculated figure of merit metrics; and provide the generated one or more correctables to a fabrication sub-system.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A illustrates a simplified block diagram of a system for performing overlay metrology with multi-merit adaptive sampling, in accordance with one or more embodiments of the present disclosure.

FIG. 1B illustrates a simplified block diagram of the system for performing overlay metrology with multi-merit adaptive sampling, in accordance with one or more embodiments of the present disclosure.

FIG. 2 illustrates a process flow diagram depicting a method for multi-merit adaptive sampling, in accordance with one or more embodiments of the present disclosure.

FIG. 3 illustrates a graphic representation of the relationship between hot spot area distribution over time, in accordance with one or more embodiments of the present disclosure.

FIG. 4 illustrates a graphic representation of the relationship between hot spot area distribution over time, in accordance with one or more embodiments of the present disclosure.

FIG. 5A illustrates a plot depicting the relationship between correctable coefficients and cost of ownership, in accordance with one or more embodiments of the present disclosure.

FIG. 5B illustrates a plot depicting the relationship between on-product overlay and cost of ownership, in accordance with one or more embodiments of the present disclosure.

FIG. 6A illustrates a plot depicting sampling plans for a fixed sampling technique.

FIG. 6B illustrates a plot depicting sampling plans for the system and method for multi-merit adaptive sampling, in accordance with one or more embodiments of the present disclosure.

FIG. 7 illustrates a conceptual view of an overlay metrology sub-system, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to a system and method for multi-merit adaptive sampling in overlay metrology. In particular, the multi-merit adaptive sampling system and method may target critical areas on the sample (e.g., hot spots) and subsequently update the fabrication tool's correction process to minimize the requirement for extensive sampling, thus leading to enhanced efficiency and greater measurement accuracy. For example, the system and method of the present disclosure may reduce the need for increased sampling due to the analysis of model stability and convergence of model elements to multiple Key Performance Indicators (KPIs) and accuracy merits (or figure of merits). Further, the multi-merit adaptive sampling system and method may dynamically adjust the sampling point based on the calculated accuracy merits, thereby decreasing the number of sampling points over time. For example, after analyzing the first sample, areas associated with high process variation and low process variation may be identified, such that an adjusted sampling map may be generated based on the calculated accuracy merits.

For purposes of the present disclosure “overlay” refers to a vector that quantifies the precision of alignment between a newly imprinted lithographic pattern and a pre-existing pattern on the sample, evaluated at any location on the sample. In other words, the vector that represents the precision of the position at which a lithographic pattern has been imprinted, in relation to a fixed coordinate grid, evaluated at any given location on the sample. Given that the goal of overlay control is to reduce the misalignment of the actual device pattern, as determined post-etching process (AEI), it is of paramount importance to characterize the systematic discrepancy accurately and consistently between the After Development Inspection (ADI) and AEI overlay, referred to as Non-Zero Offset (NZO). Applying precise NZO to the scanner through the Advanced-Process-Control (APC) loop facilitates effective control of the scanner overlay following the post-lithography ADI stage.

It is contemplated herein that the multi-merit adaptive sampling system and method as disclosed herein may reduce the cost of ownership for several reasons. For example, the system and method of the present disclosure may reduce material costs by reducing the frequency of sampling, thus decreasing the overall consumption of materials which leads to cost savings. By way of another example, process efficiency may be improved due to the fewer sampling steps which means quicker processing times during manufacturing. This efficiency gain translates into cost savings in terms of reduced labor costs, decreased energy consumption, and improved overall production throughput. Additionally, the system and method of the present disclosure may reduce wase. For example, sampling generates waste in terms of unused materials and defective components. By minimizing sampling, the amount of waste generated is reduced, contributing to cost savings in waste disposal and recycling efforts. By way of another example, the system and method of the present disclosure may decrease equipment utilization. By reducing the number of samplings, these high-cost equipment assets can be utilized more efficiently across the manufacturing process, optimizing their return on investment. Further, by streamlining the sampling process, fewer skilled workers may be needed, leading to a reduction in labor costs associated with training and employing highly specialized staff. Furthermore, the system and method of the present disclosure may improve the cycle time by lowering the number of sampling steps, thus leading to a faster overall production cycle. This not only reduces the time it takes to bring a semiconductor product to market but also minimizes associated costs such as financing and holding inventory. Additionally, the system and method of the present disclosure enhances yield by providing a more targeted and efficient sampling strategy, leading to better understanding and control of the manufacturing process, thereby reducing defects and improving yield. Higher yields mean more usable semiconductor products from the same amount of input materials, further contributing to cost reduction. The overall cost of quality may also be decreased. With improved process control and reduced variability through strategic sampling, the cost associated with quality control and defect resolution is minimized. This includes costs related to rework, warranty claims, and customer support.

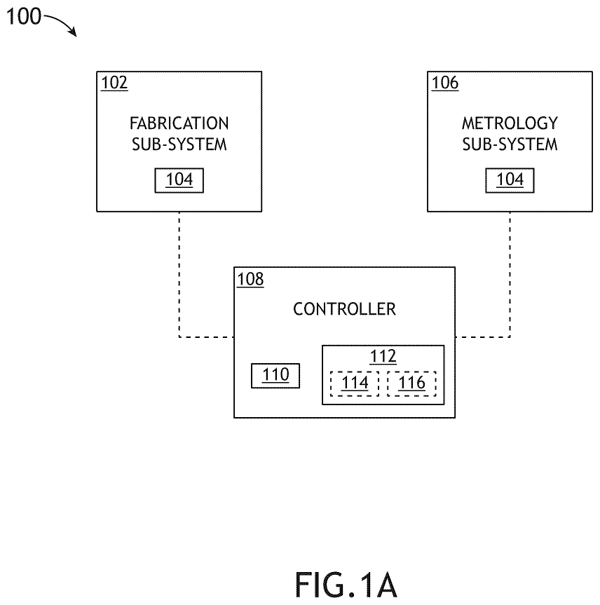

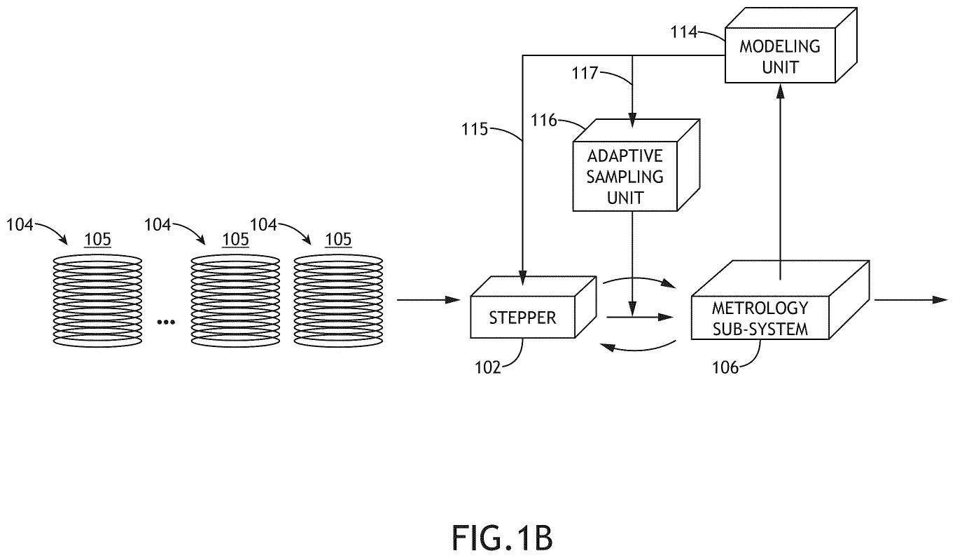

FIGS. 1A-1B illustrate simplified block diagrams of a sampling system 100, in accordance with one or more embodiments of the present disclosure.

In embodiments, the sampling system 100 includes a fabrication sub-system 102 configured to process one or more samples 104 in one or more lots 105. For example, the fabrication sub-system 102 may include a stepper or scanner of a lithography tool. For instance, the stepper may be configured to process the one or more samples 104 in the one or more lots 105. The one or more lots 105 may include any number of lots with any number of samples. In a non-limiting example, each lot 105 may include twenty-five samples (or wafers), where there is up to an N number of lots (N being an integer greater than 1).

It is contemplated that the one or more samples 104 may include any sample known in the art including, but not limited to, a wafer, a reticle/photomask, and the like.

In embodiments, the sampling system 100 includes a metrology sub-system 106 configured to perform one or more measurements on the one or mor samples 104. For example, the metrology sub-system 106 may be configured to perform one or more measurements on the one or more samples 104 after the one or more lots 105 of the samples 104 have been processed through the stepper (or scanner).

In embodiments, the metrology sub-system 106 proposes (or suggests) a plurality of figure of merit metrics (or accuracy merits). For example, the metrology sub-system 106 may generate (or provide) non-measurement sample data when performing measurements on the samples 104. For purposes of the present disclosure, the term “figure of merits”, “accuracy merits”, “merits”, or variations thereof may refer to additional data associated with process variation of the sample (separate from physical sample of the sample).

It is contemplated that the figure of merits may include any suitable accuracy metric indicative of process variation such as, but not limited to, static NZO map (sNZO), overlay, change in focus, Quality Merit (QM), Pupil-R, Measurement Error Bar (MEB), Contrast Precision (CP), Kernel 3σ (K3s or kernel 3sigma), AIM Periodic Ratio (APR), Grey Levels (GL), Reflectivity, Overlay Sensitivity, Region Boundary Indicator (RBI), Pupil 3s (P3s or pupil 3sigma), and the like.

It is noted that the metrology sub-system 106 may include any type of metrology sub-system 106 known in the art. For example, the metrology sub-system 106 may include an optical-based metrology tool. By way of another example, the metrology sub-system 106 may include an image-based metrology tool.

In embodiments, the sampling system 100 includes a controller 108 including one or more processors 110 and memory 112.

In embodiments, the sampling system 100 further includes a modeling unit 114. For example, the modeling unit 114 may include one or more modeling algorithms (or models) configured to generate one or more sets of modeling data. In one instance, as will be discussed further herein, the modeling unit 114 may be configured to generate stepper modeling data 115 to be provided to the stepper. In another instance, as will be discussed further herein, the modeling unit 114 may be configured to generate adaptive sampling modeling data 117 to be provided to an adaptive sampling unit 116.

In embodiments, the one or more processors 110 of the sampling system 100 may include the modeling unit 114 stored in memory 112 on the controller 108. For example, in a non-limiting example, the modeling unit 114 may be run on the sampling system 100 during measurement runtime to generate the stepper modeling data 115 and/or adaptive sampling modeling data 117 in real-time (e.g., “on the fly”).

In embodiments, the sampling system 100 further includes the adaptive sampling unit 116 configured to dynamically update the sampling plan based on at least the sampling model data 117. For example, as will be discussed further herein, the adaptive sampling unit 116 may be configured to generate one or more adjusted sampling maps including an adjusted set of sampling points. In one instance, the adaptive sampling unit 116 may generate an adjusted sampling map for an additional sample 104 in the same lot as the first sample 104, such that the adjusted sampling map is fed-backwards to the metrology sub-system 106 before measurement of said additional sample 104. In another instance, the adaptive sampling unit 116 may generate an adjusted sampling map for a future process layer of the first sample 104, such that the adjusted sampling map is fed-forward to the stepper before the metrology sub-system 106 performs measurement on the future process layer of the first sample 104. In this regard, feedforward control may be employed for the current layer, such that the static NZO for a previous layer with resist may be known and utilized in the sampling map.

In embodiments, the one or more processors 110 of the sampling system 100 may include the modeling unit 114 stored in memory 112 on the controller 108. For example, in a non-limiting example, the modeling unit 114 may be run on the sampling system 100 during measurement runtime to generate modeling data 115, 117 in real-time (e.g., “on the fly”).

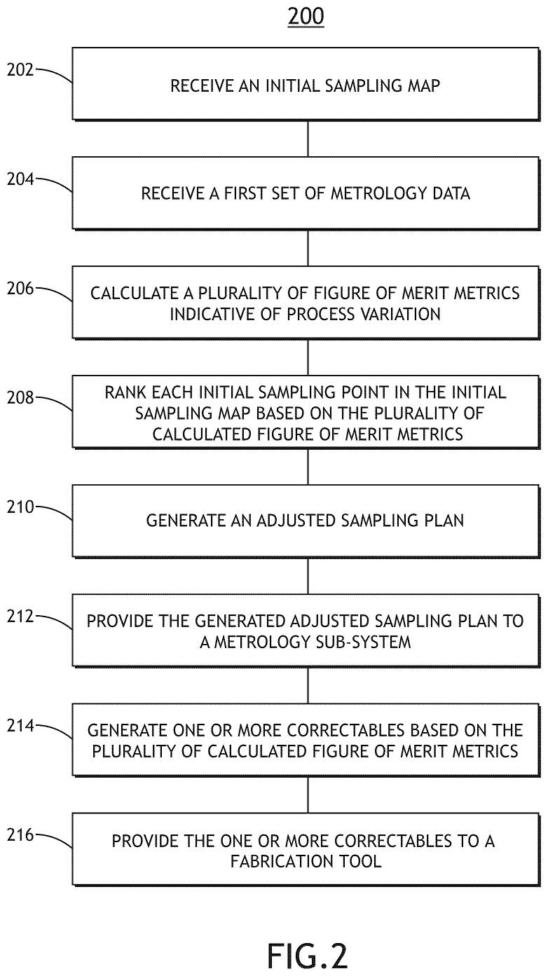

FIG. 2 illustrates a flowchart of a method 200 for multi-merit adaptive sampling, in accordance with one or more embodiments of the present disclosure. Applicant notes that the embodiments and enabling technologies described previously herein in the context of the control system 100 should be interpreted to extend to method 200. It is further noted, however, that the method 200 is not limited to the architecture of the control system 100.

In a step 202, an initial sampling map may be received. For example, the one or more processors 110 may be configured to receive an initial sample map of a sample 104, where the initial sampling map includes a first set of sampling points. For instance, the first sample in the lot (or batch) may be loaded into the stepper of the fabrication sub-system 102 and an initial sampling number for the first sample in the lot (or batch) may be set.

For purposes of the present disclosure, the term “sampling map” or “site map” is generally defined as a map including a set of points (or sites) where a metrology sub-system will need to perform measurements.

In embodiments, the initial sampling map is generated based on historical data from previous samples. For example, an analysis of previous samples in the lot and/or previous lots may be performed using an algorithm or model. For instance, the algorithm may be configured to generate an initial sampling map with a low number of sampling points based on the best stability, performed on previous samples (in the lot/previous lots). In this regard, the historical data may be used to identify an initial sampling configuration that strikes on the balance between precision and efficiency.

It is contemplated herein that the one or more processors 110 of the system 100 may perform such analysis to generate the initial sampling map or the one or more processors 110 of the system 100 may receive the initial sampling map from a remote controller configured to perform such analysis.

In a step 204, a first set of metrology data may be received. For example, the metrology sub-system 106 may be configured to perform one or more measurements on a first sample in the lot based on the initial sampling map (received in step 202). For instance, once the initial sampling number has been set, the metrology sub-system 106 may acquire metrology data for the first sample in the lot using overlay analysis.

In a step 206, a plurality of figure of merit metrics indicative of process variation may be calculated. For example, the one or more processors 110 may be configured to calculate a plurality of figure of merit metrics for the sample.

In embodiments, the metrology sub-system 106 may propose a plurality of figure of merit metrics and provide the proposed plurality of figure of merit metrics to the modeling unit 114. For example, the modeling unit 114 may calculate the plurality of figure of merit metrics and generate a plurality of figure of merit maps.

In an optional step, the plurality of figure of merit maps may be combined to generate a combined figure of merit map. For example, the plurality of figure of merit maps may be combined into a single figure of merit map using a response surface method, as generally discussed in U.S. Pat. No. 11,062,928, issued on Jul. 13, 2021, which is incorporated herein by reference in the entirety. For instance, it is contemplated herein that the analysis of merits from the metrology sub-system 106 may be performed on-the-fly using a statistical model such as, analysis of variance (ANOVA). In this regard, one or more parameters (or settings) of the metrology sub-system 106 may be adjusted, such parameters may include, but are not limited to, mark design, aperture settings, polarization settings, illumination bandwidth, wavelength, and focus. It is contemplated herein that ANOVA may be used to analyze the variance between different groups or treatments. In this regard, ANOVA may be used to determine whether there are significant differences among means and provides insights into the impact of various factors on the response variable.

In embodiments, individual merit scores may be first normalized to composite values ranging from 0 to 1, where 1 represents the ideal composite score. The specific function applied may depend on the response goal (e.g., maximize, minimize, or target). Such desirability method may include pre-determined specification limits, which serve as thresholds for calculations. By setting lower and upper specification limits based on best-known methods or semiconductor manufacturer requirements, the process may be adjusted.

It is contemplated herein that ANOVA serves as a screening process, allowing users to identify and ignore insignificant parameters. This approach reduces the problem size, making it more manageable. Additionally, alternative techniques beyond ANOVA may also be utilized without departing from the scope of the present disclosure.

It is contemplated herein that unifying of figure of merit maps may enhance the stepper's (or scanner's) control and increase the accuracy.

In a step 208, each initial sampling point in the initial sampling map may be ranked based on the plurality of calculated figure of merit metrics. For example, the one or more processors 110 may be configured to rank each initial sampling point in the initial sampling map based on the calculated figure of merit metrics. For instance, the one or more processors 110 may rank the initial sampling points based on one or more levels of process variation associated with the calculated figure of merit metrics. In this regard, regions on the sample with low stability (or high levels of process variation) may be prioritized in the denser points grid of the map for enhanced sampling in these areas and regions on the sample with high stability (or low levels of process variation) may be de-prioritized in the points grid to decrease sampling in these areas. As previously discussed herein, dense sampling strategies uniformly increase sampling across the sample, such that areas with low process variation are unnecessarily measured. It is contemplated herein that the individual ranking of the sampling points based on the figure of merit metrics may provide a more tailored, adaptive sampling strategy, such that sampling is only increased in select areas associated with high process variation (as determined by the multiple figure of merit metrics). For example, NZO may be weighted higher (e.g., ranked higher).

For purposes of the present disclosure, the term “hot spots” and variations thereof generally refer to specific regions of a sample that exhibit higher levels of process variability. It is contemplated herein that these “hot-spots” may be areas where precise and accurate measurements are essential to ensure proper alignment. As such, identifying and characterizing these areas are crucial for quality control and process optimizations, since they can significantly impact the process yield and decreases CoO.

In a step 210, an adjusted sampling map may be generated. For example, the one or more processors 110 may be configured to generate an adjusted sampling map for at least one of an additional sample in the same (or different lot) or a future process layer of the same sample, where the adjusted sampling map includes an adjusted set of sampling points (different from the first set of initial sampling points).

In embodiments, the adjusted set of sampling points are generated by increasing a number of sampling points in a first region on the sample 104 associated with a first level of process variation and decreasing a number of sampling points in an additional region on the sample 104 associated with a second level of process variation. For example, the first region on the sample 104 may be a hot spot region 300 associated with a high level of process variation and the second region on the sample 104 may be a region associated with a low level of process variation.

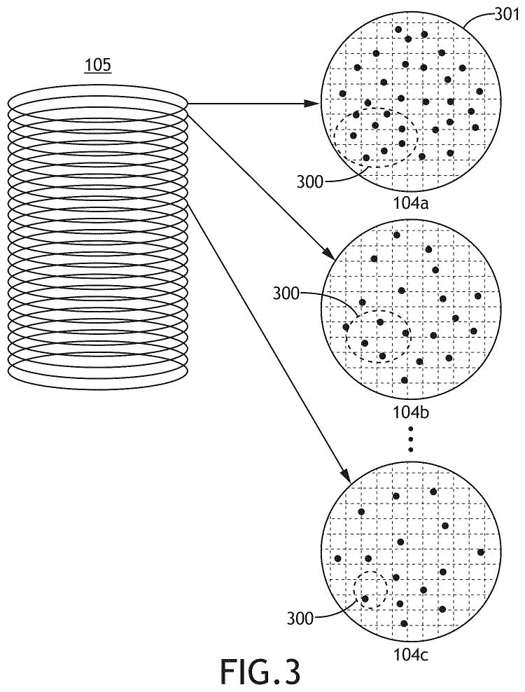

FIG. 3 illustrates sampling maps 301 of the one or more samples 104a-c, in accordance with one or more embodiments of the present disclosure. For example, as shown in FIG. 3, a first sample 104a may include a sampling map 301 having a first hot spot distribution area 300 including a first number of points, a second sample 104b may include a sampling map 301 having a second hot spot distribution area 300 including a second number of points, and a third sample 104c may include a sampling map 301 having a third hot spot distribution area 300 including a third number of points, where the number of points may decrease over time, thereby improving the sampling technique.

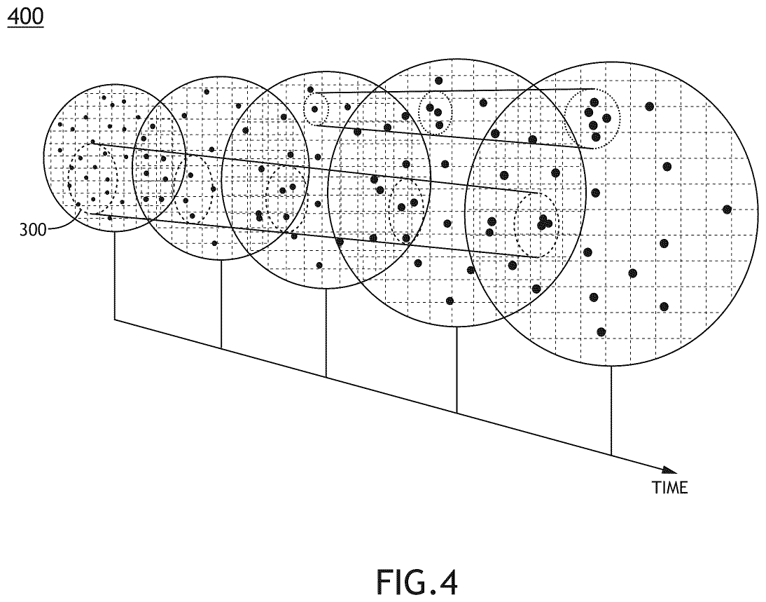

FIG. 4 illustrates a plot 400 depicting the distribution of the hot spot areas 300 over time using the multi-merit adaptive sampling technique disclosed here, in accordance with one or more embodiments of the present disclosure. For example, the plot 400 depicts a graphical representation showing the decrease of the dispersion of “hot-spots” over time due to multi-merit adaptive sampling scheme. As shown in FIG. 4, there is a high concentration of sampling points on the first sample. As time progresses, indicated by the labeled “Time”, the number of sampling points decreases due to adaptive sampling scheme.

In embodiments, the adjusted sampling map may be refined until each of the sampling points have stabilized. For example, one or more of the previous steps 202-210 may be repeated until each of the sampling points have stabilized. In other words, the number of sampling points on the adjusted sampling map may be updated until there is convergence of the model elements.

In a step 212, the generated adjusted sampling plan may be provided to a metrology sub-system. For example, the one or more processors 110 may be configured to provide the adjusted sampling map to the metrology sub-system 106 and direct the metrology sub-system 106 to perform the one or more measurements on at least one of the additional sample 104 in the same (or different) lot 105 or a future process layer of the same sample 104 based on the adjusted sample map. It is contemplated herein that the generated adjusted sampling plan may be provided to the metrology sub-system 106 during measurement runtime.

In a step 214, one or more correctables may be generated based on the plurality of calculated figure of merit metrics. For example, the one or more processors 110 may be configured to generate the one or more correctables based on the plurality of calculated figure of merit metrics.

It is contemplated herein that the one or more correctables may include any suitable correctable for the fabrication sub-system 102 such as, but not limited to, translation correctables, scanning correctables, rotation correctables, magnification correctables, or the like.

In a step 216, the generated one or more correctables may be provided a fabrication tool. For example, the one or more processors 110 may provide the one or more correctables to the stepper during measurement runtime. In this regard, the generated of one or more correctables is simultaneously performed during the measurement of overlay.

It is contemplated herein that multi-merit adaptive sampling technique as disclosed herein may provide numerous benefits. For example, as previously noted herein, the multi-merit adaptive sampling system and method disclosed herein minimizes the need for extensive sampling on the sample. Thus, by introducing a more efficient and targeted sampling approach, the semiconductor industry can significantly reduce costs associated with materials, testing processes, and resource utilization. Further, the system and method of present disclosure not only streamlines the production cycle but also enhances yield prediction accuracy, minimizing unnecessary expenditures. Thereby substantially lowering the overall cost of ownership for semiconductor manufacturers, making the technology more economically viable and competitive in the market.

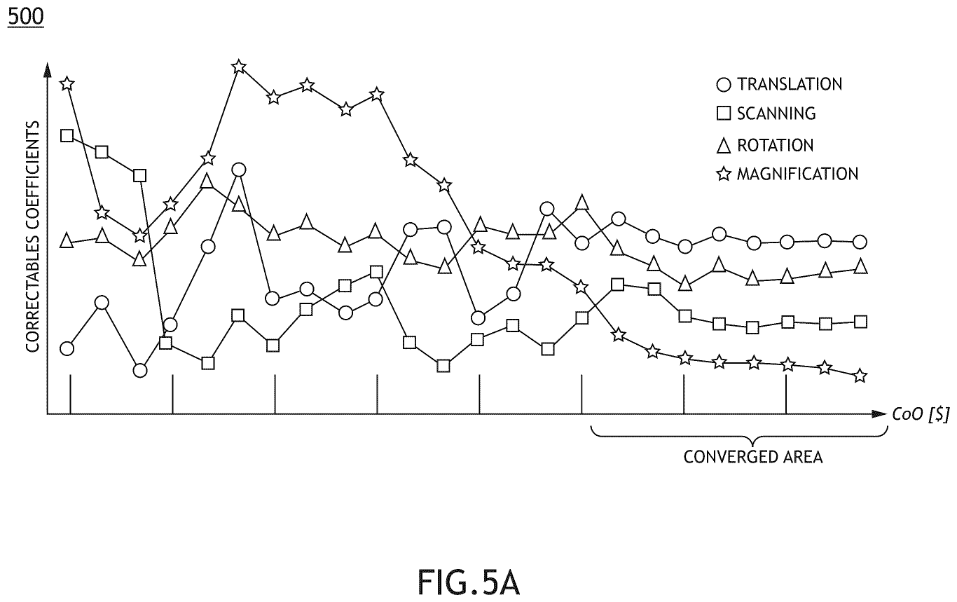

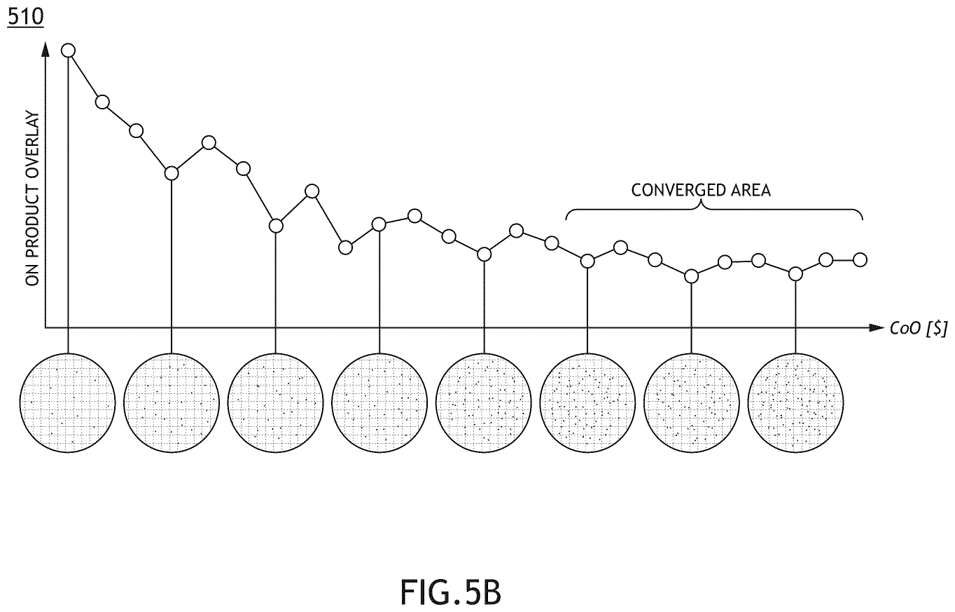

FIG. 5A illustrates a plot 500 depicting the relationship between a plurality of correctable coefficients and CoO (in dollars), in accordance with one or more embodiments of the present disclosure. FIG. 5B is a plot 510 depicting the relationship between on-product overlay and CoO (in dollars), in accordance with one or more embodiments of the present disclosure. Referring to FIG. 5A, generally the higher the CoO (e.g., dollars spent), the more stable the correctable coefficients are. However, the multi-merit adaptive sampling technique aims to decrease the CoO while obtaining stable correctable coefficients. Referring to FIG. 5B, generally more accurate on-product overlay measurements are obtained through increased sampling, which is associated with an increased CoO (e.g., dollars spent). However, the multi-merit adaptive sampling technique aims to decrease the CoO while obtaining accurate on-product overlay measurements and through enhanced sampling (without uniformly increasing sampling across the sample).

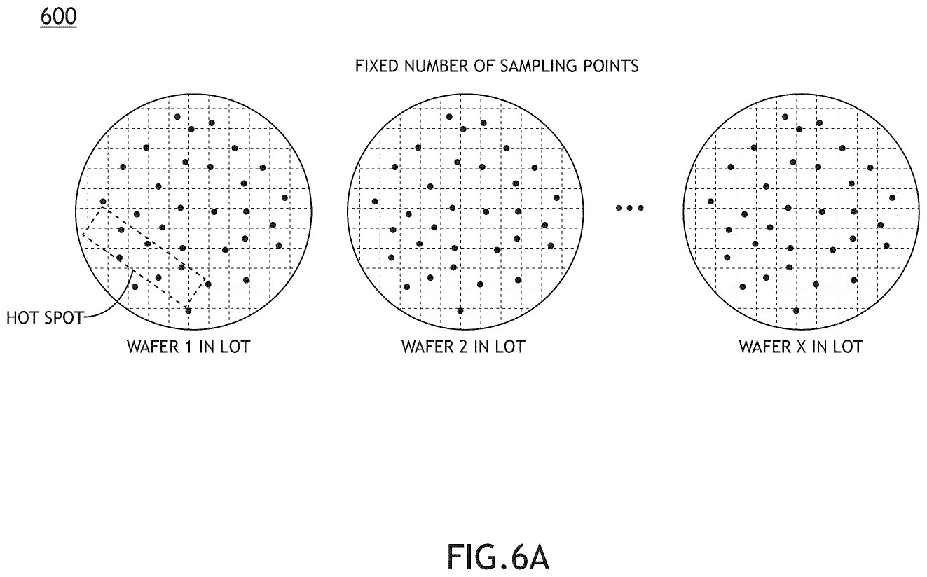

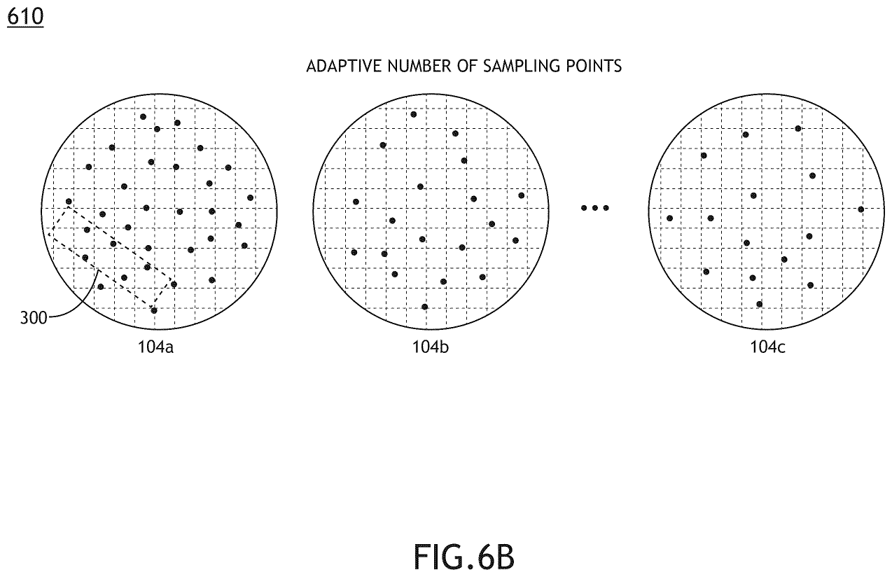

FIGS. 6A-6B illustrate a comparison between a fixed sampling technique and the multi-merit adaptive sampling technique as disclosed herein. Referring to FIG. 6A, plot 600 depicts a plurality of samples in the lot, where a constant (or fixed) number of sampling points is used during production. In comparison, referring to FIG. 6B, plot 610 depicts a plurality of samples 104a-c in the lot 105, where the number of sampling points is dynamically updated. As shown in FIG. 6B, over time the number of sampling points decreases and additionally there is a shrinkage in distribution of “hots spots” areas. Conversely, as shown in FIG. 6A, with a fixed sampling technique the “hot spot” areas do not decrease over time, but rather stay the same. This pictorial representation suggests that the adaptive nature of the present disclosure lowers the number of sampling points, thus leading to a reduction in cost of ownership (CoO).

Referring to FIG. 1A, in embodiments, the metrology sub-system 106 includes an overlay metrology sub-system 106 to acquire overlay signals from overlay targets on the sample 104 based on any number of overlay recipes. For example, the overlay metrology sub-system may direct illumination to a sample 104 and may further collect radiation emanating from the sample 104 to generate an overlay signal suitable for the determination of overlay of two or more sample layers. The overlay metrology sub-system may be any type of overlay metrology sub-system known in the art suitable for generating overlay signals suitable for determining overlay associated with overlay targets on a sample 104. The overlay metrology sub-system 106 may operate in an imaging mode or a non-imaging mode. For example, in an imaging mode, individual overlay target elements may be resolvable within the illuminated spot on the sample (e.g., as part of a bright-field image, a dark-field image, a phase-contrast image, or the like). By way of another example, the overlay metrology sub-system 106 may operate as a scatterometry-based overlay metrology sub-system in which radiation from the sample is analyzed at a pupil plane to characterize the angular distribution of radiation from the sample 104 (e.g., associated with scattering and/or diffraction of radiation by the sample 104).

Further, the overlay sub-system may be configurable to generate overlay signals based on any number of recipes defining measurement parameters for the acquiring an overlay signal suitable for determining overlay of an overlay target. For example, a recipe of an overlay metrology sub-system may include, but is not limited to, an illumination wavelength, a detected wavelength of radiation emanating from the sample, a spot size of illumination on the sample, an angle of incident illumination, a polarization of incident illumination, a position of a beam of incident illumination on an overlay target, a position of an overlay target in the focal volume of the overlay metrology sub-system, or the like.

In embodiments, the controller 108 is communicatively coupled to the overlay metrology sub-system 106. The controller 108 may be configured to direct the overlay metrology sub-system 106 to generate overlay signals based on one or more selected recipes. The controller 108 may be further configured to receive data including, but not limited to, overlay signals from the overlay metrology sub-system 106. Additionally, the controller 108 may be configured to determine overlay associated with an overlay target based on the acquired overlay signals.

In embodiments, the controller 108 includes one or more processors 110. For example, the one or more processors 110 may be configured to execute a set of program instructions maintained in a memory device 112, or memory. The one or more processors 110 of a controller 108 may include any processing element known in the art. In this sense, the one or more processors 110 may include any microprocessor-type device configured to execute algorithms and/or instructions. Further, the memory device 112 may include any storage medium known in the art suitable for storing program instructions executable by the associated one or more processors 110. For example, the memory device 112 may include a non-transitory memory medium. As an additional example, the memory device 112 may include, but is not limited to, a read-only memory, a random access memory, a magnetic or optical memory device (e.g., disk), a magnetic tape, a solid state drive and the like. It is further noted that memory device 112 may be housed in a common controller housing with the one or more processors 110.

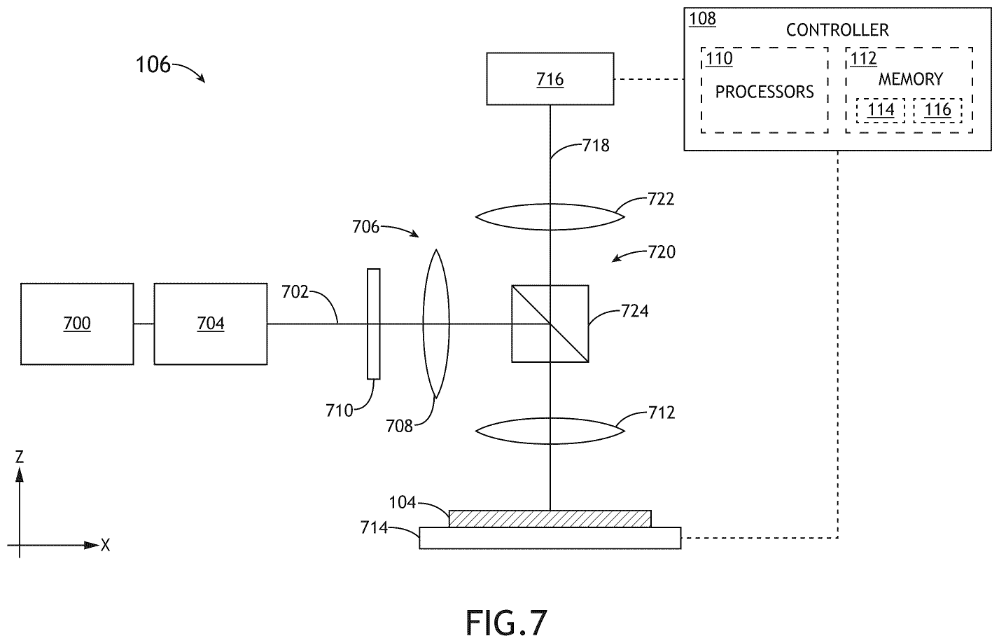

FIG. 7 illustrates a conceptual view illustrating the overlay metrology sub-system 106, in accordance with one or more embodiments of the present disclosure. In embodiments, the overlay metrology sub-system 106 includes an illumination source 700 configured to generate an illumination beam 702. The illumination beam 702 may include one or more selected wavelengths of light including, but not limited to, ultraviolet (UV) radiation, visible radiation, or infrared (IR) radiation.

The illumination source 700 may include any type of illumination source suitable for providing an illumination beam 702. In embodiments, the illumination source 700 is a laser source. For example, the illumination source 700 may include, but is not limited to, one or more narrowband laser sources, a broadband laser source, a supercontinuum laser source, a white light laser source, or the like. In this regard, the illumination source 700 may provide an illumination beam 702 having high coherence (e.g., high spatial coherence and/or temporal coherence). In embodiments, the illumination source 700 includes a laser-sustained plasma (LSP) source. For example, the illumination source 700 may include, but is not limited to, a LSP lamp, an LSP bulb, or a LSP chamber suitable for containing one or more elements that, when excited by a laser source into a plasma state, may emit broadband illumination. In embodiments, the illumination source 700 includes a lamp source. For example, the illumination source 700 may include, but is not limited to, an arc lamp, a discharge lamp, an electrode-less lamp, or the like. In this regard, the illumination source 700 may provide an illumination beam 702 having low coherence (e.g., low spatial coherence and/or temporal coherence).

In embodiments, the overlay metrology sub-system 106 includes a wavelength selection device 704 to control the spectrum of the illumination beam 702 for illumination of the sample 104. For example, the wavelength selection device 704 may include a tunable filter suitable for providing an illumination beam 702 with a selected spectrum (e.g., center wavelength, bandwidth, spectral profile, or the like). By way of another example, the wavelength selection device 704 may adjust one or more control settings of a tunable illumination source 700 to directly control the spectrum of the illumination beam 702. Further, the controller 108 may be communicatively coupled to the illumination source 700 and/or the wavelength selection device 704 to adjust one or more aspects of the spectrum of the illumination beam 702.

In embodiments, the overlay metrology sub-system 106 directs the illumination beam 702 to the sample 104 via an illumination pathway 706. The illumination pathway 706 may include one or more optical components suitable for modifying and/or conditioning the illumination beam 702 as well as directing the illumination beam 702 to the sample 104. For example, the illumination pathway 706 may include, but is not required to include, one or more lenses 708 (e.g., to collimate the illumination beam 702, to relay pupil and/or field planes, or the like), one or more polarizers 710 to adjust the polarization of the illumination beam 702, one or more filters, one or more beam splitters, one or more diffusers, one or more homogenizers, one or more apodizers, one or more beam shapers, or one or more mirrors (e.g., static mirrors, translatable mirrors, scanning mirrors, or the like). In embodiments, the overlay metrology sub-system 106 includes an objective lens 712 to focus the illumination beam 702 onto the sample 104 (e.g., an overlay target with overlay target elements located on two or more layers of the sample 104).

In embodiments, the sample 104 is disposed on a sample stage 714 suitable for securing the sample 104 and further configured to position the sample 104 with respect to the illumination beam 702.

In embodiments, the overlay metrology sub-system 106 includes one or more detectors 716 configured to capture radiation emanating from the sample 104 (e.g., an overlay target on the sample 104) (e.g., sample radiation 718) through a collection pathway 720 and generate one or more overlay signals indicative of overlay of two or more layers of the sample 104. The collection pathway 720 may include multiple optical elements to direct and/or modify illumination collected by the objective lens 712 including, but not limited to one or more lenses 722, one or more filters, one or more polarizers, one or more beam blocks, or one or more beamsplitters. For example, a detector 716 may receive an image of the sample 104 provided by elements in the collection pathway 720 (e.g., the objective lens 712, the one or more lenses 722, or the like). By way of another example, a detector 716 may receive radiation reflected or scattered (e.g., via specular reflection, diffuse reflection, and the like) from the sample 104. By way of another example, a detector 716 may receive radiation generated by the sample (e.g., luminescence associated with absorption of the illumination beam 702, and the like). By way of another example, a detector 716 may receive one or more diffracted orders of radiation from the sample 104 (e.g., 0-order diffraction, ±1 order diffraction, ±2 order diffraction, and the like).

The detector 716 may include any type of optical detector known in the art suitable for measuring illumination received from the sample 104. For example, the detector 716 may include, but is not limited to, a charge-coupled device (CCD) detector, a time-delay integration (TDI) detector, a photomultiplier tube (PMT), an avalanche photodiode (APD), a complementary metal-oxide-semiconductor (CMOS) sensor, or the like. In embodiments, the detector 716 may include a spectroscopic detector suitable for identifying wavelengths of light emanating from the sample 104.

The illumination pathway 706 and the collection pathway 720 of the overlay metrology sub-system 106 may be oriented in a wide range of configurations suitable for illuminating the sample 104 with the illumination beam 702 and collecting radiation emanating from the sample 104 in response to the incident illumination beam 702. For example, as illustrated in FIG. 7, the overlay metrology sub-system 106 may include a beamsplitter 724 oriented such that the objective lens 712 may simultaneously direct the illumination beam 702 to the sample 104 and collect radiation emanating from the sample 104. By way of another example, the illumination pathway 706 and the collection pathway 720 may contain non-overlapping optical paths.

As described previously herein, the overlay metrology sub-system 106 may be configurable to generate overlay signals associated with overlay marks on the sample 104 using any number of overlay recipes (e.g., sets of measurement parameters). Further, the overlay metrology sub-system 106 may provide rapid tuning of the measurement parameters such that multiple overlay signals based on different recipes may be rapidly acquired. For example, the controller 108 of the overlay metrology sub-system 106 may be communicatively coupled with one or more adjustable components of the overlay metrology sub-system 106 to configure the adjustable components in accordance with an overlay recipe.

An overlay recipe may include one or more aspects of the spectrum of the illumination beam 702 incident on the sample such as, but not limited to the wavelength (e.g., the central wavelength), the bandwidth, and the spectral profile of the illumination beam 702 as measurement parameters. For example, the controller 108 may be communicatively coupled to the illumination source 700 and/or the wavelength selection device 704 to adjust the spectrum of the illumination beam 702 in accordance with an overlay recipe.

In embodiments, the wavelength selection device 704 includes one or more position-tunable spectral filters in which spectral characteristics of an incident illumination beam 702 (e.g., a center wavelength, a bandwidth, a spectral transmissivity value or the like) may be rapidly tuned by modifying the position of the illumination beam 702 on the filter. Further, position-tunable spectral filters may include any type of spectral filter such as, but not limited to, a low-pass filter, a high-pass filter, a band-pass filter, or a band-reject filter.

For example, a position-tunable spectral filter may include one or more thin films operating as an edge filter with a position-tunable cutoff wavelength. In this regard, the cutoff wavelength may be tuned by modifying the position of the illumination beam 702 on the filter. For instance, a low-pass edge filter may pass (e.g., via transmission or reflection) wavelengths below the cutoff wavelength, whereas a high-pass edge filter may pass wavelengths above the cutoff wavelength. Further, a band-pass filter may be formed from a low-pass edge filter combined with a high-pass edge filter.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A system comprising:
a controller communicatively coupled to a metrology sub-system and a fabrication sub-system, the controller including one or more processors configured to execute program instructions configured to cause the one or more processors to:
receive an initial sampling map for at least a first sample of the one or more samples in a first lot of the one or more sample lots, wherein the initial sampling map includes a first set of sampling points;
receive a first set of metrology data from at least the first sample of the one or more samples from the metrology sub-system based on the first set of sampling points of the initial sampling map;
calculate a plurality of figure of merit metrics indicative of process variation based on the first set of metrology data;
rank each initial sampling point of the first set of sampling points in the initial sampling map based on the plurality of calculated figure of merit metrics and one or more levels of process variation;
generate an adjusted sampling plan for at least one of a second sample of the one or more samples in the first lot of the one or more sample lots or a future process layer of the first sample of the one or more samples in the first lot based on the rank of each initial sampling point of the first set of sampling points, wherein the adjusted sampling plan includes an adjusted set of sampling points different than the first set of sampling points, wherein the adjusted set of sampling points is generated by increasing a number of sampling points in a first sample region of the first sample associated with a first level of process variation and decreasing a number of sampling points in a second sample region of the first sample associated with a second level of process variation, wherein the first level of process variation is greater than the second level of process variation;
provide the generated adjusted sampling plan to the metrology sub-system; and
generate one or more correctables based on the plurality of calculated figure of merit metrics.

2. The system of claim 1, wherein the controller is further configured to:
generate a combined figure of merit map based on the plurality of calculated figure of merit metrics.

3. The system of claim 1, wherein the initial sample number is based on an algorithm of best stability performed on previous samples in the lot.

4. The system of claim 1, wherein the plurality of figure of merit metrics comprise at least one of:
static non-zero offset, overlay, change in focus, quality merit, pupil-R, measurement error bar, contrast precision, kernel 3sigma, AIM periodic ratio, grey levels, reflectivity, overlay sensitivity, region boundary indicator, or pupil 3sigma.

5. The system of claim 1, wherein the metrology sub-system comprises an image-based metrology sub-system.

6. The system of claim 1, wherein the metrology sub-system comprises a scatterometry-based metrology sub-system.

7. They system of claim 1, wherein the generated adjusted sampling plan is provided to the metrology sub-system during runtime.

8. The system of claim 1, wherein the controller is further configured to:
provide the generated one or more correctables to a fabrication tool.

9. They system of claim 8, wherein the generated one or more correctables are provided to the fabrication tool during runtime.

10. They system of claim 8, wherein the fabrication sub-system comprises a lithography tool.

11. A system comprising:
a metrology sub-system configured to perform metrology measurements on one or more samples in one or more sample lots; and
a controller communicatively coupled to the metrology sub-system, the controller including one or more processors configured to execute program instructions configured to cause the one or more processors to:
receive an initial sampling map for at least a first sample of the one or more samples in a first lot of the one or more sample lots, wherein the initial sampling map includes a first set of sampling points;
receive a first set of metrology data from at least the first sample of the one or more samples from the metrology sub-system based on the first set of sampling points of the initial sampling map;
calculate a plurality of figure of merit metrics indicative of process variation based on the first set of metrology data;
rank each initial sampling point of the first set of sampling points in the initial sampling map based on the plurality of calculated figure of merit metrics and one or more associated levels of process variation;
generate an adjusted sampling plan for at least one of a second sample of the one or more samples in the first lot of the one or more sample lots or a future process layer of the first sample of the one or more samples in the first lot based on the rank of each initial sampling point of the first set of sampling points, wherein the adjusted sampling plan includes an adjusted set of sampling points different than the first set of sampling points, wherein the adjusted set of sampling points is generated by increasing a number of sampling points in a first sample region of the first sample associated with a first level of process variation and decreasing a number of sampling points in a second sample region of the first sample associated with a second level of process variation, wherein the first level of process variation is greater than the second level of process variation;
provide the generated adjusted sampling plan to the metrology sub-system; and
generate one or more correctables based on the plurality of calculated figure of merit metrics.

12. The system of claim 11, wherein the controller is further configured to:
generate a combined figure of merit map based on the plurality of calculated figure of merit metrics.

13. The system of claim 11, wherein the initial sample map is based on an algorithm of best stability performed on previous samples in the lot.

14. The system of claim 11, wherein the plurality of figure of merit metrics comprise at least one of:
static non-zero offset, overlay, change in focus, quality merit, pupil-R, measurement error bar, contrast precision, kernel 3sigma, AIM periodic ratio, grey levels, reflectivity, overlay sensitivity, region boundary indicator, or pupil 3sigma.

15. The system of claim 11, wherein the metrology sub-system comprises an image-based metrology sub-system.

16. The system of claim 11, wherein the metrology sub-system comprises a scatterometry-based metrology sub-system.

17. They system of claim 11, wherein the generated adjusted sampling plan is provided to the metrology sub-system during runtime.

18. The system of claim 11, wherein the system further comprises:
a fabrication tool communicatively coupled to the controller, wherein the controller is further configured to provide the generated one or more correctables to a fabrication tool.

19. They system of claim 18, wherein the generated one or more correctables are provided to the fabrication tool during runtime.

20. They system of claim 18, wherein the fabrication tool comprises a lithography tool.

21. A method comprising:
receiving an initial sampling map for at least a first sample of one or more samples in a first lot of one or more sample lots, wherein the initial sampling map includes a first set of sampling points;
generating a first set of metrology data from at least the first sample of the one or more samples using a metrology sub-system based on the first set of sampling points of the initial sampling map;
calculating a plurality of figure of merit metrics indicative of process variation based on the first set of metrology data;
ranking each initial sampling point of the first set of sampling points in the initial sampling map based on the plurality of calculated figure of merit metrics and one or more associated levels of process variation;
generating an adjusted sampling plan for at least one of a second sample of the one or more samples in the first lot of the one or more sample lots or a future process layer of the first sample of the one or more samples in the first lot based on the rank of each initial sampling point of the first set of sampling points, wherein the adjusted sampling plan includes an adjusted set of sampling points different than the first set of sampling points, wherein the adjusted set of sampling points is generated by increasing a number of sampling points in a first sample region of the first sample associated with a first level of process variation and decreasing a number of sampling points in a second sample region of the first sample associated with a second level of process variation, wherein the first level of process variation is greater than the second level of process variation;
providing the generated adjusted sampling plan to the metrology sub-system;
generating one or more correctables based on the plurality of calculated figure of merit metrics; and
providing the generated one or more correctables to a fabrication sub-system.
